(19) United States
(12) Patent Application Publication
(10) Pub. No.: US 2009/0190426 A1
(43) Pub. Date: Jul. 30, 2009

(54) CIRCUITS, METHODS AND DESIGN STRUCTURES FOR ADAPTIVE REPAIR OF SRAM ARRAYS

(75) Inventors: Ching-Te K. Chuang, South Salem, NY (US); Jae-Joon Kim, Austin, TX (US); Niladri N. Mojumder, West Lafayette, IN (US); Saibal Mukhopadhyay, Atlanta, GA (US)

Correspondence Address: RYAN, MASON & LEWIS, LLP, 1300 POST ROAD, SUITE 205, FAIRFIELD, CT, 06824, US

(73) Assignee: International Business Machines Corporation, Armonk, NY (US)

(21) Appl. No.: 12/019,132

(22) Filed: Jan. 24, 2008

(51) Int. Cl. G11C 29/44

(52) U.S. Cl. 365/210.11; 365/201

(57) ABSTRACT

The circuit includes a static random access memory array having a plurality of cells, in turn having a plurality of devices; as well as a global sensor having at least one output, coupled to the static random access memory array, and configured to sense at least one of global readability and global write-ability. Also included is a decision-making circuit coupled to the at least one output of the global sensor. The decision-making circuit is configured to determine, from the at least one output of the global sensor, whether adaptation signals are required to correct global readability and/or write-ability. An adaptation signal generation block is also included and is coupled to the decision-making circuit and the array, and configured to supply the adaptation signals to the array, responsive to the decision-making circuit determining that the adaptation signals are required. At least the array and the global sensor, and preferably the decision-making circuit and the adaptation signal generation block as well, are implemented on a single integrated circuit chip. An associated method and design structure(s) are also provided.

### STATEMENT REGARDING FEDERALLY SPONSORED RESEARCH OR DEVELOPMENT

This invention was made with Government support under contract number HR0011-07-9-0002 awarded by the Defense Advanced Research Projects Agency (DARPA). The government has certain rights in this invention.

### FIELD OF THE INVENTION

The present invention generally relates to electronic circuitry, with associated methods and design structures, and, more particularly, to electronic memory circuits with associated methods and design structures.

### BACKGROUND OF THE INVENTION

Random variations in the device characteristics during processing (for example, mismatch in threshold voltages, line-edge roughness, and the like) can result in read and write failures in static random access memory (SRAM) cells, which in turn results in yield degradation. Both (i) global systematic variation (which affects all the n-type metal oxide semiconductor (NMOS) and p-type metal oxide semiconductor (PMOS) devices in an SRAM die similarly) and (ii) local random variation (which can result in mismatch between devices in a cell) contribute to yield degradation. Global systematic variation and local device mismatch are shown at 102, 104, respectively in FIG. 1. The conflicting requirements for read and write stabilities in SRAM cells limit the opportunity for improvement in cell robustness against local random variation via cell transistor sizing and/or static assignment of cell terminal voltages. Hence, most prior efforts in improving cell robustness against local random variation are focused on dynamic control of cell terminal voltages, depending on read and write operations.

The conventional 6-transistor (6T) SRAM cell 400, depicted in FIG. 1, includes a first inverter formed by p-type and n-type field effect transistors (PFET and NFET, respectively) PL and NL (numbered 402 and 404), cross-coupled to a second inverter formed by PFET PR and NFET NR, numbered 406, 408. The cross-coupled inverters are connected to a voltage supply node 410 and a ground 412. Left and right NFET access devices SL, SR, numbered 414 and 416, interconnect true bit line 418 and complementary bit line 420 to storage nodes 426, 424 under control of word line 422.

U.S. Pat. No. 5,796,651 to Home et al. discloses a memory device using a reduced word line voltage during read operations and a method of accessing such a memory device. In the Horne et al. reference, a memory device uses a reduced word line voltage during READ operations. The memory device includes a memory cell and a pass transistor for accessing the cell. The cell includes a storage node coupled to a pull-down transistor having substantially the same conductivity as the pass transistor. A drive circuit generates a reduced word line voltage to activate the pass transistor during a READ operation. The reduced word line voltage has a magnitude less than the magnitude of the bias voltage used to activate the pull-down transistor.

United States Patent Publication No. 2006-0067134 of Zhang et al. discloses a dynamic multi-V_{cc} scheme for SRAM cell stability control. The dynamic multi-voltage memory array features SRAM cells that are subjected to different biasing conditions, depending on the operating mode of the cells. The selected SRAM cell receives a first voltage when a read operation is performed, and receives a second voltage when a write operation is performed. By biasing the cell differently for the two distinct operations, a total decoupling of the read and write operations is achieved.

### SUMMARY OF THE INVENTION

Principles of the present invention provide techniques for adaptive repair of SRAM arrays.

In an exemplary embodiment, according to one aspect of the invention, a static random access memory circuit includes a static random access memory array having a plurality of cells, in turn having a plurality of devices; as well as a global sensor having at least one output, coupled to the static random access memory array, and configured to sense at least one of global readability and global write-ability. Also included is a decision-making circuit coupled to the at least one output of the global sensor. The decision-making circuit is configured to determine, from the at least one output of the global sensor, whether adaptation signals are required to correct global readability and/or write-ability. An adaptation signal generation block is also included and is coupled to the decision-making circuit and the array, and configured to supply the adaptation signals to the array, responsive to the decision-making circuit determining that the adaptation signals are required. At least the array and the global sensor, and preferably the decision-making circuit and the adaptation signal generation block as well, are implemented on a single integrated circuit chip.

In another aspect, an exemplary method for compensating static random access memory chips includes the steps of obtaining a plurality of chips of the kind described; testing each of the chips to determine whether read and/or write compensation is required; designating the chips for which no compensation is required as “good”; performing write compensation for those of the chips where write compensation is required; performing read compensation for those of the chips where read compensation is required; and re-testing those of the chips where read and/or write compensation was performed. Those of the chips which pass the re-test are designated as “good” and those of the chips which fail the re-test are designated as “faulty.”

In still another aspect, the invention includes design structures for memory circuits of the kind described.

One or more embodiments of the present invention may be realized in the form of an integrated circuit.

These and other objects, features and advantages of the present invention will become apparent from the following detailed description of illustrative embodiments thereof, which is to be read in connection with the accompanying drawings.

### BRIEF DESCRIPTION OF THE DRAWINGS

FIG. 1 shows global systematic variation and local device mismatch, as known from the prior art;

FIG. 2 shows the interaction of global and local variation, which can be addressed according to one or more embodiments of the invention;

FIG. 3 shows a block diagram of a memory circuit, according to an aspect of the invention;

FIGS. 4 and 5 depict aspects of correction using cell terminal voltages, according to an embodiment of the invention;

FIG. 6 shows a global process plane associated with FIGS. 4 and 5;

FIG. 7 shows a block diagram for an exemplary circuit implementing correction with cell terminal voltages;

FIG. 8 shows a block diagram for an exemplary circuit implementing correction with body-bias voltages, according to another aspect of the invention;

FIG. 9 depicts a readability sensor, according to still another aspect of the invention;

FIG. 10 depicts non-limiting exemplary results of operation of the readability sensor of FIG. 9;

FIG. 11 depicts a write-ability sensor, according to yet another aspect of the invention;

FIG. 12 depicts non-limiting exemplary results of operation of the write-ability sensor of FIG. 11;

FIG. 13 is a flow chart of method steps, according to an even further aspect of the invention;

FIG. 14 shows non-limiting exemplary results of SRAM yield improvement, that can be realized according to one or more inventive techniques; and

FIG. 15 is a flow diagram of a design process used in semiconductor design, manufacture, and/or test.

### DETAILED DESCRIPTION OF PREFERRED EMBODIMENTS

One or more embodiments of the invention allow direct measurement of the global readability and/or write-ability corner of an SRAM die coming from a global process corner, and application of proper correction mechanisms to reduce the dominant type of failure. One or more embodiments of the invention offer one or more of the following benefits:
No dynamic change in signals—simple design and timing
Direct detection of the global read and write corners
Consideration of PMOS and NMOS threshold voltages (Vₜ) as separate parameters
Correction can be applied through voltage signals (V_{dd} and/or V_{cs})—can be used for partially-depleted silicon-on-insulator (PD/SOI).

One or more embodiments of the invention can be used, for example, in current and/or future microprocessor products having large on-chip SRAM caches, with minimal changes in the cells and arrays, for parametric yield enhancement

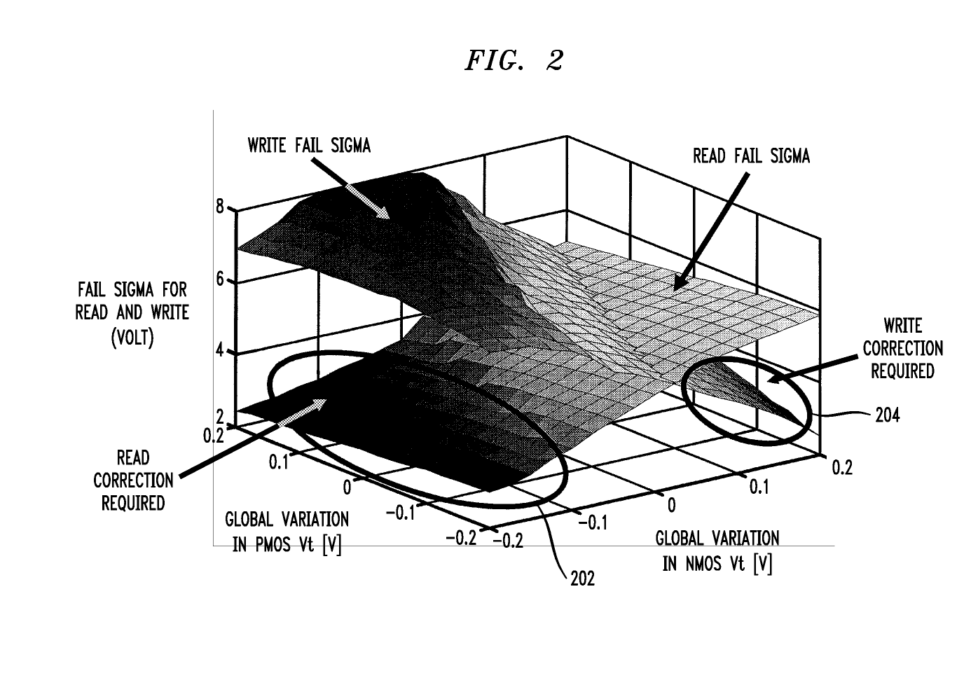

FIG. 2 shows that the fail sigma (higher fail sigma implies a more robust cell) of a cell due to local random variation depends on the global process corner. Global variation in threshold voltage (Vₜ) for PMOS and NMOS are shown on the X-Y axes, with the read and write sigma, in volts, on the Z axis. The read fail sigma worsens at the low-threshold voltage NMOS and high-threshold voltage PMOS corners, whereas the write fail sigma worsens at the low-threshold voltage PMOS and high-threshold voltage NMOS corners. Hence, application of cell terminal voltages (or body-bias voltages) suitable for the read operation at the bad read corners will help correct the faulty dies from that corner. On the other hand, application of cell terminal voltages (or body-bias voltages) suitable for the write operation at the bad write corners will help correct the faulty dies from that corner. The areas requiring read and write correction are labeled as 202, 204 respectively.

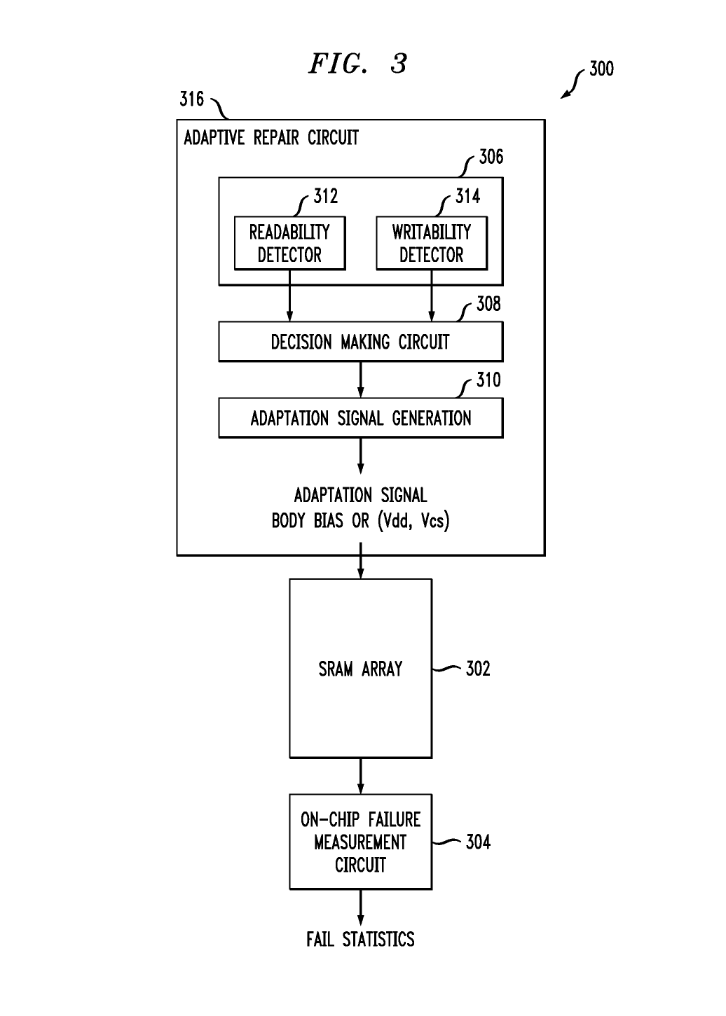

FIG. 3 is a block diagram 300 of an exemplary inventive SRAM array with adaptive repair mechanism. It includes the SRAM; array 302 with on-chip circuits 304 coupled to array 302 for failure characterization, a global readability and write-ability sensor 306, a circuit 308 configured to make a decision on whether read or write correction is required, and a circuit 310 configured to generate the adaptation signals. The adaptation signals can be cell terminal voltages (which require less process and/or design overhead, and are believed advantageous for PD/SOI technology) or the body-bias voltages for PMOS and NMOS devices. SRAM array 302 is preferably a conventional SRAM array with a plurality of bit lines structures, such as formed by the pair of true and complementary bit lines 418, 420; a plurality of word line structures, such as word line 422, and a plurality of cells 400 at cell locations formed by the intersection of the bit line structures and word line structures. However, in some instances, non-conventional SRAM arrays, such as those with cells other than standard six-transistor cells, may also benefit from inventive techniques.

Block 306 may include, for example, readability detector 312 and write-ability detector 314. Blocks 306, 308, 310 together form adaptive repair circuit 316. In a preferred embodiment, all the blocks in FIG. 3 are implemented on a single integrated circuit. In any event, at least the array 302 and the global sensor 306 should be implemented on a single integrated circuit chip, to accurately track the process variations.

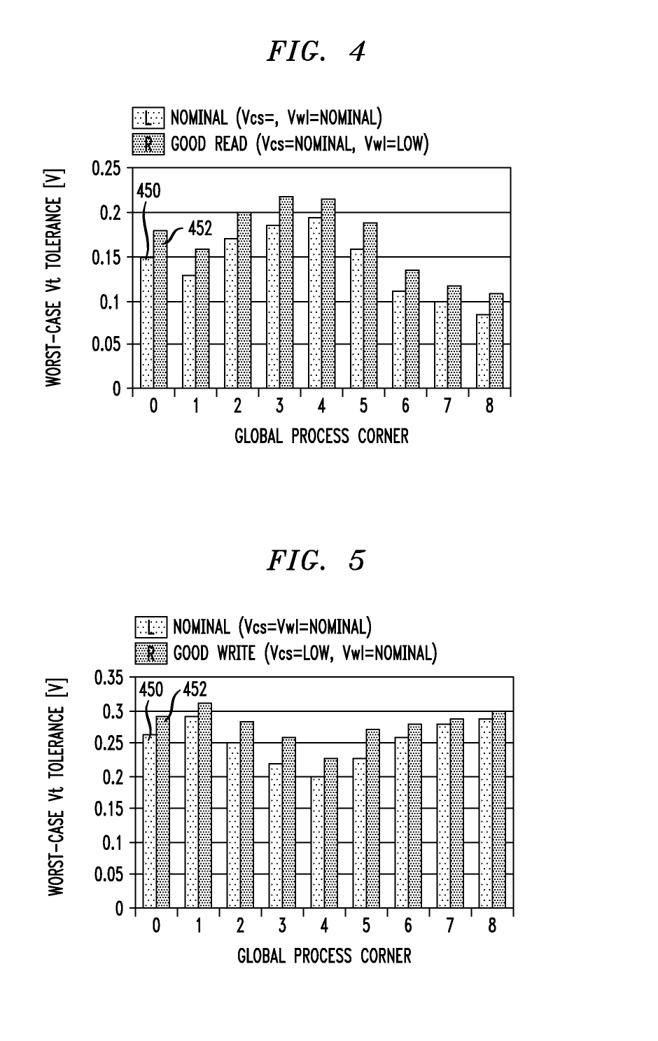

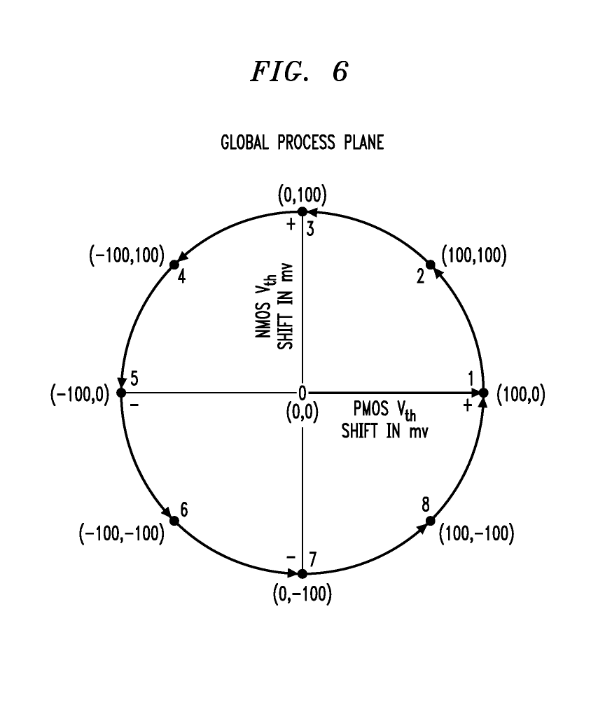

FIGS. 4 and 5 illustrate non-limiting exemplary simulation results measuring the worst-case local threshold voltage variation that needs to be applied to an exemplary cell to cause a read or write failure (simulations for 45 nm SOI SRAM cell). They show that, at different process corners, use of lower word line voltage and nominal cell supply voltage (FIG. 4) improves the tolerance to local threshold voltage variation during a read operation. On the other hand, the local threshold voltage variation tolerance of the write operation improves with a lower cell supply voltage and nominal word line voltage, as shown in FIG. 5. Note that in FIGS. 4 and 5, the nominal case is shown in the left-most band 450 and the “Good Read” or “Good Write” respectively in the right-most band 452. Global process corners 0 through 8, on the X-axes of FIGS. 4 and 5, are shown on the global process plane in FIG. 6.

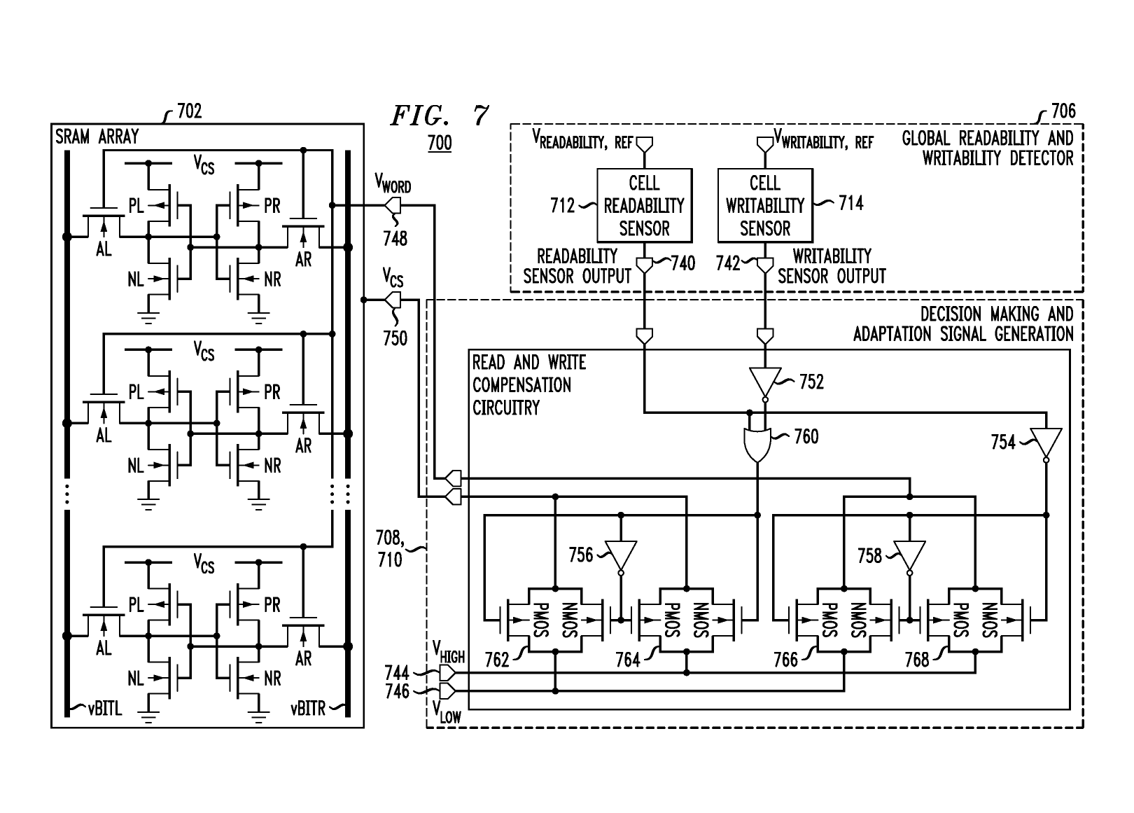

FIG. 7 shows a block diagram for an exemplary circuit 700 implementing correction with cell terminal voltages. Elements that represent non-limiting specific implementations of the blocks of FIG. 3 have received the same reference character incremented by 400. The readability and write-ability sensor 706 detects the global readability and write-ability corner. It detects whether a read correction (Readability Sensor Output 740 has a logic level of “one”) or a write correction (Write-ability Sensor Output 742 has a logic level of “one”) is required. Depending on the results of such detection, the decision making and adaptation signal generation block 708, 710 applies a proper voltage (V_{high}, supplied at 744 or V_{low}, supplied at 746) to the word line (V_{word}) and cell supply terminal (V_{cs}), numbered 748, 750, respectively (using the observations from FIGS. 4-6). Block 708, 710 can be implemented, for example, using inverters 752, 754, 756, 758; OR gate 760; and four PMOS-NMOS pairs 762, 764, 766, 768 (in each case, the PMOS transistor is on the left and the NMOS transistor is on the right). When output 740 has a logic level of “one,” block 708, 710 applies low voltage 746 to word line terminal 748, while when output 742 has a logic level of “one,” block 708, 710 applies low voltage 746 to supply terminal 750. Array 702 includes a plurality of cells similar to cells 400, each with terminals similar to terminal 410 connected to terminal 750, with word lines coupled (as appropriate) to word line terminal 748. For brevity and illustrative convenience, the cells, and their devices, within array 702 are not separately numbered.

Note that cell terminal voltages and/or word line voltages below nominal values are preferred for reliability, but in the general case, voltages off nominal values can be employed in accordance with the teachings herein. Further, once adaptation in accordance with one or more embodiments of the invention is applied, terminal voltages and/or word line voltages can be fixed for both the read and write cases.

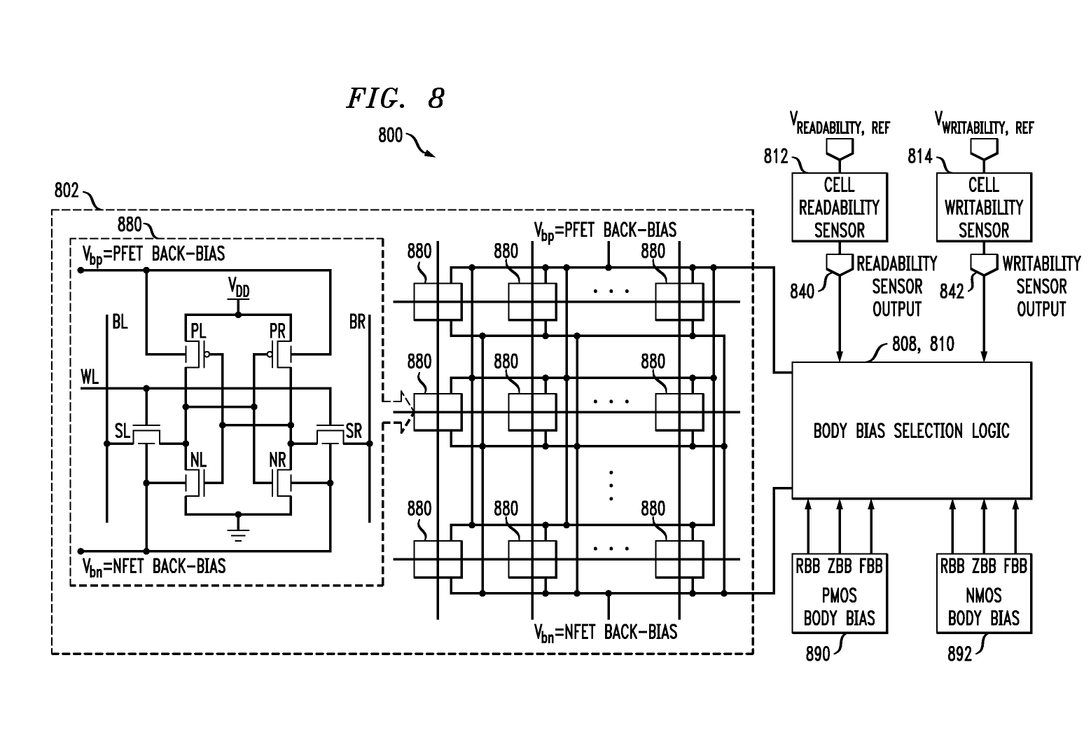

FIG. 8 shows a block diagram for an exemplary circuit 800 implementing correction with body-bias voltages, according to another aspect of the invention. Blocks 812, 814 with outputs 840, 842 function similarly to blocks 712, 714 with outputs 740, 742 in FIG. 7. The adaptation signal in circuit 800 is applied through the NMOS and PMOS body biases. In this case, the body terminals of all of the PMOS and NMOS devices are connected together and the selection circuit 808, 810 (so numbered because it represents a non-limiting specific implementation of blocks 308, 310 of FIG. 3) selects the proper bias level for PMOS and NMOS body voltages. A supply block 890 makes available PMOS body bias levels of RBB, ZBB, and FBB; while a supply block 892 makes available NMOS body bias levels of RBB, ZBB, and FBB. For readability problems FBB can be applied for PMOS and RBB for NMOS, while for write-ability problems RBB can be applied for PMOS and FBB for NMOS. Note that RBB stands for Reverse Body Bias, ZBB stands for Zero change in Body Bias from nominal body bias, and FBB stands for Forward Body Bias. It will thus be appreciated that one or more embodiments of the invention check the global read stability and write-ability, thus inherently addressing skewed process conditions. Array 802 includes a number of cells 880, which may be generally similar to cell 400, with all six devices PL, PR, NL, NR, SL, and SR having body terminals for application of body bias. Devices PL, PR receive PFET back bias V_{bp}, while the other four devices receive NFET back bias V_{bn}.

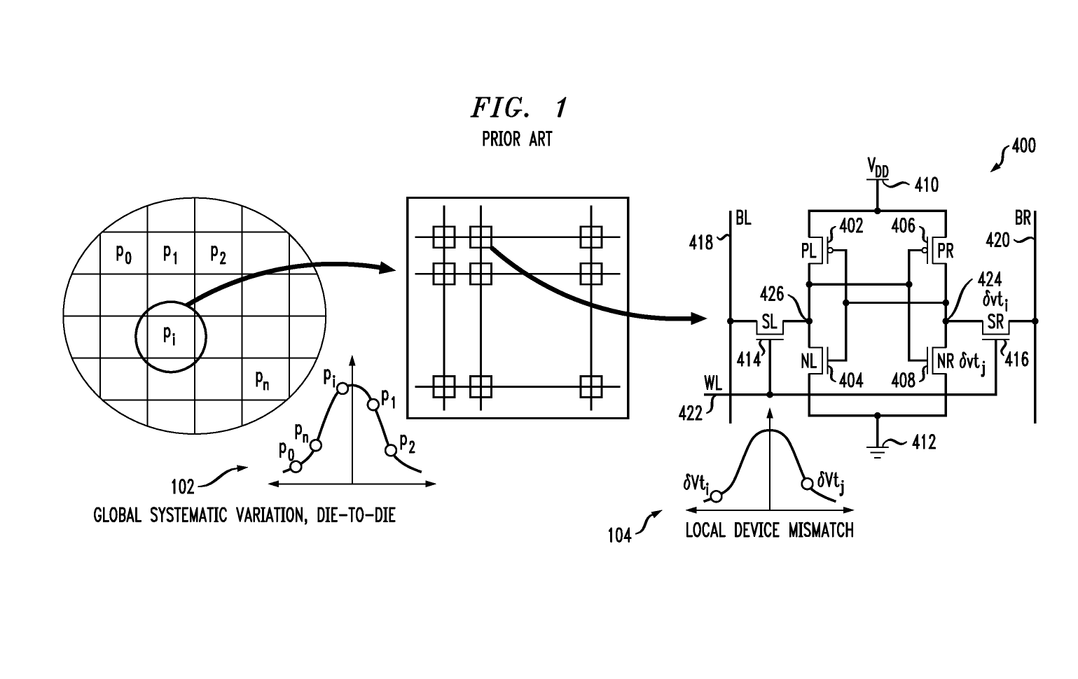

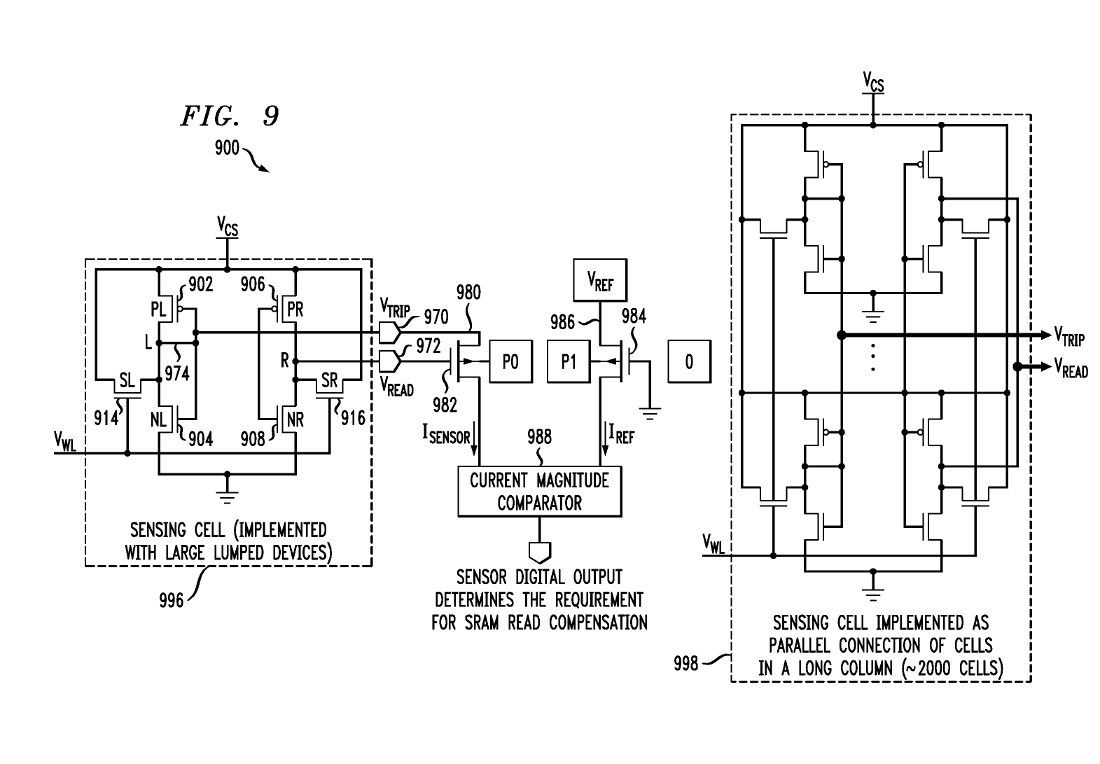

FIG. 9 depicts an exemplary embodiment of a readability sensor 900, with two different types of sensing cells. To sense the readability, the embodiment of FIG. 9 monitors the difference between trip voltage (Vₜᵣᵢₚ) of the half-cell composed of PL, SL, NL, at terminal 970, and the read voltage (V_{read}) of the half-cell composed of PR, NR, SR, at terminal 972. The devices are numbered using even numbers from 902 to 916, and have the analogous numbers to devices 402 to 416 in FIG. 1, incremented by five hundred. To measure the trip voltage, the input and output of the inverter PL-NL are connected, as shown at 974; the SL device has its gate at voltage V_{wl} and its drain at voltage V_{cs}; the feedback path connecting nodes “L” and “R” is eliminated; and the voltage at node “L” is measured.

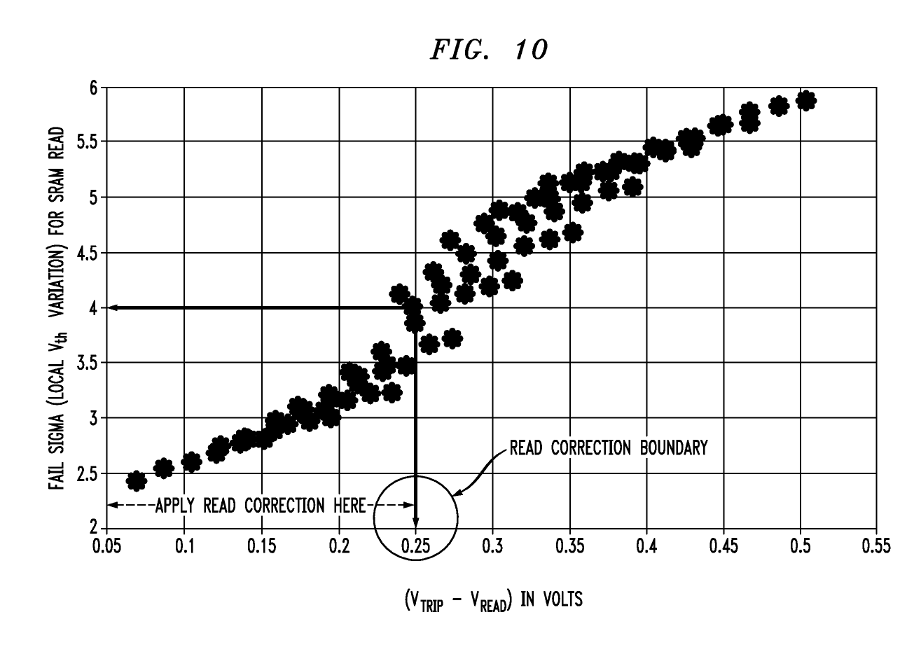

To measure read voltage, the gates of PR and NR are connected to V_{cs}; the gate of SR is maintained at V_{wl}; the drain of SR is maintained at V_{cs}; the connection between nodes “R” and “L” is removed, and the voltage at node “R” is measured. Next, Vₜᵣᵢₚ 970 and V_{read} 972 are connected, respectively, to the drain 980 and gate 982 of one PMOS, P0, of a differential PMOS pair. The other PMOS of the pair, P1, has gate 984 at GND and drain 986 at read reference voltage V_{ref}. The currents through the two PMOS devices P0, P1 are compared using a current comparator 988. The differential pair needs to be properly matched. A larger value of Vₜᵣᵢₚ−V_{read} indicates better readability, and SRAM cells with higher Vₜᵣᵢₚ−V_{read} have a larger read fail sigma, as illustrated in FIG. 10. If Vₜᵣᵢₚ−V_{read} falls below a certain level (V_{read,ref}), which corresponds to a minimum tolerable value of read fail sigma, then current through the reference PMOS (P1) becomes higher than that through the sensing PMOS (P0), and output of the current comparator 988 indicates that read correction is required. The SRAM cell used for sensing read and/or trip voltages needs to be designed with large devices, to minimize the effect of local variation on those voltages, as shown at 996. This can also be achieved by properly configuring and connecting a large number actual SRAM cells in parallel, as illustrated at 998 in FIG. 9. The latter approach, as at 998, will capture the impact of cell layout on global variation better, but may have a larger area overhead.

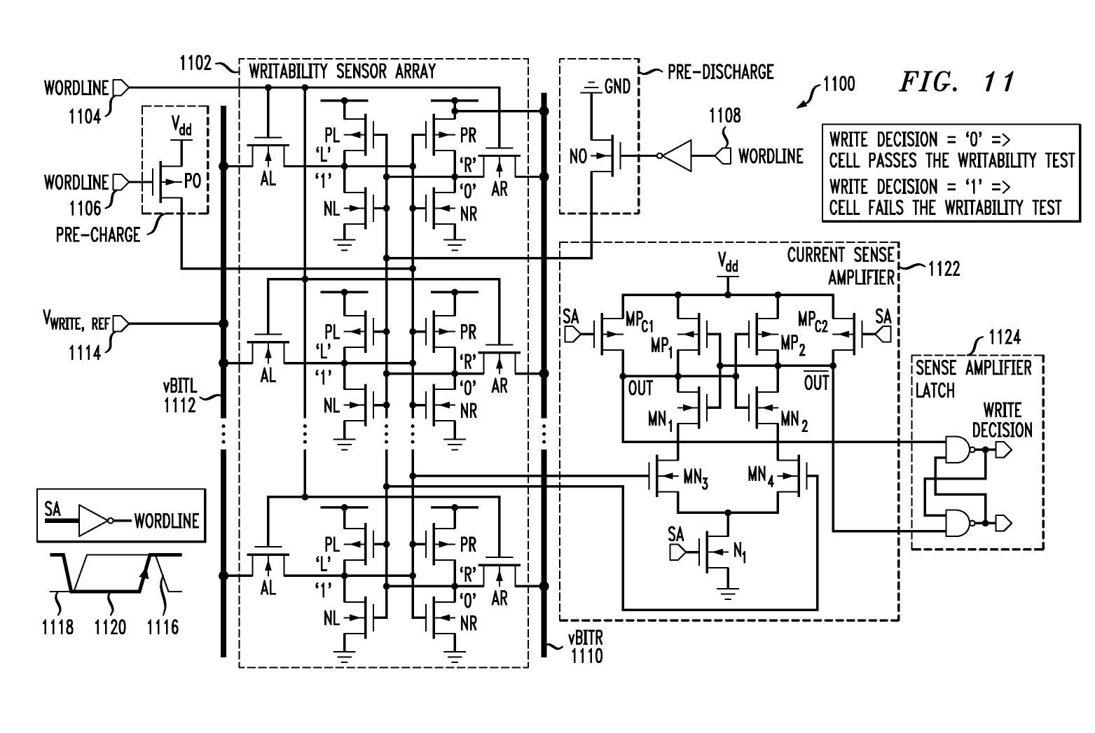

FIG. 11 depicts an exemplary embodiment of a (“global”) write-ability sensor 1100, according to another aspect of the invention. For use as a write-ability sensor, the SRAM cell is designed with large devices (or designed by connecting a number of cells in parallel, as shown in write-ability sensor array 1102). Further, for use as a write-ability sensor, the single SRAM cell with large devices, or the plurality of parallel-connected cells 1102, are configured as normal SRAM cells 400, to capture the feedback effect, which plays an important role in the write operation. First, when the word line signal 1104 is low, the node “L” is pre-charged to a logical “one” via terminal 1106, and the node “R” is pre-discharged to a logical zero, via terminal 1108. The bit line R, 1110, is held at V_{DD} whereas a voltage V_{write,ref} (>0) is applied at the bit line “L,” 1112, via terminal 1114. When the WL signal goes high for a proper write operation, the node “L” will discharge to a logical zero, whereas the node “R” will be charged to a logical one.

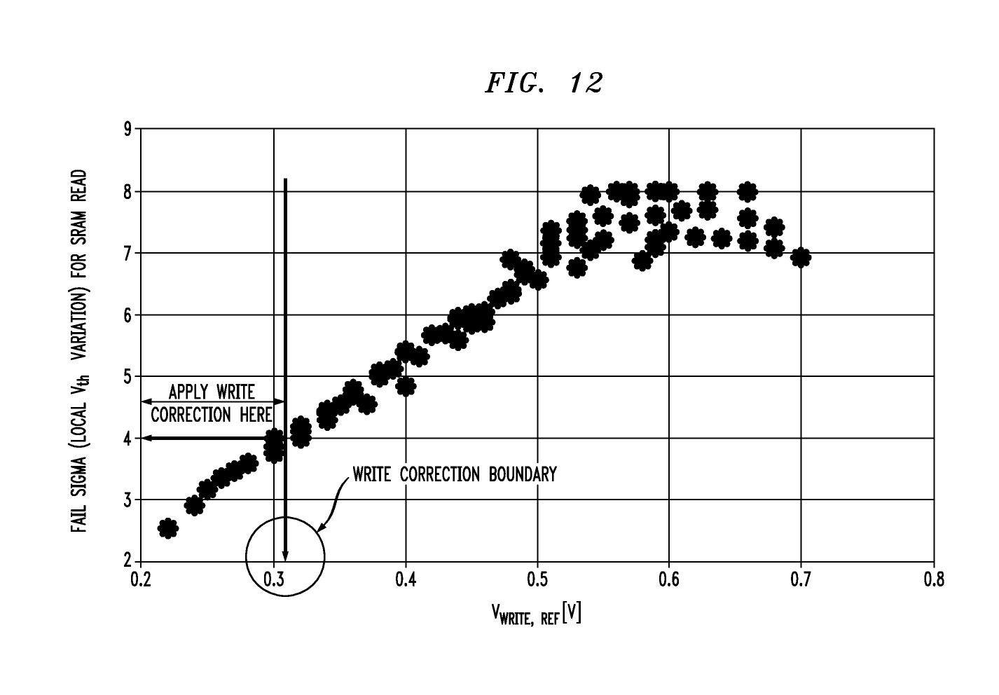

Both the nodes are sampled at the negative edge 1116 of the word line signal 1118, and compared. Note that word line signal 1118 is shown with normal weight lines while SA signal 1120 is shown with bold lines. If node “L” is observed to be less than node “R” at that time, the comparator indicates that the write operation is correct. If a correct write operation can be performed at a higher value of V_{write,ref}, it indicates that the write-ability of the cell is very high. Hence, for global corners which have good write-ability (i.e., are less prone to write fails) it is possible to perform a correct write operation even with a high value of V_{write,ref}. This is illustrated in FIG. 12, which shows that a higher value of V_{write,ref} corresponds to a higher write fail sigma. From FIG. 12, the reference value of V_{write,ref} can be selected which corresponds to a minimum tolerable write fail sigma. During measurement, this V_{write,ref} value is applied to all the SRAM dies. For the SRAM arrays where a proper write operation cannot be achieved for this reference value of V_{write,ref}, the sensor indicates that a write correction is required. Note that, since this sensor operates using the transient WL signal, it also captures the frequency dependence of write failures. The aforementioned functionality can be achieved, for example, by using current sense amplifier 1122 with latch 1124, and with sense amplifier “SA” signal 1120 applied as shown. As in the case of the “global readability sensor,” in this case also the devices in the sensor cell either need to be large, or the sensor cell needs to be designed by connecting a large number of actual cells in parallel, to minimize the impact of local random variability, as shown at 1102.

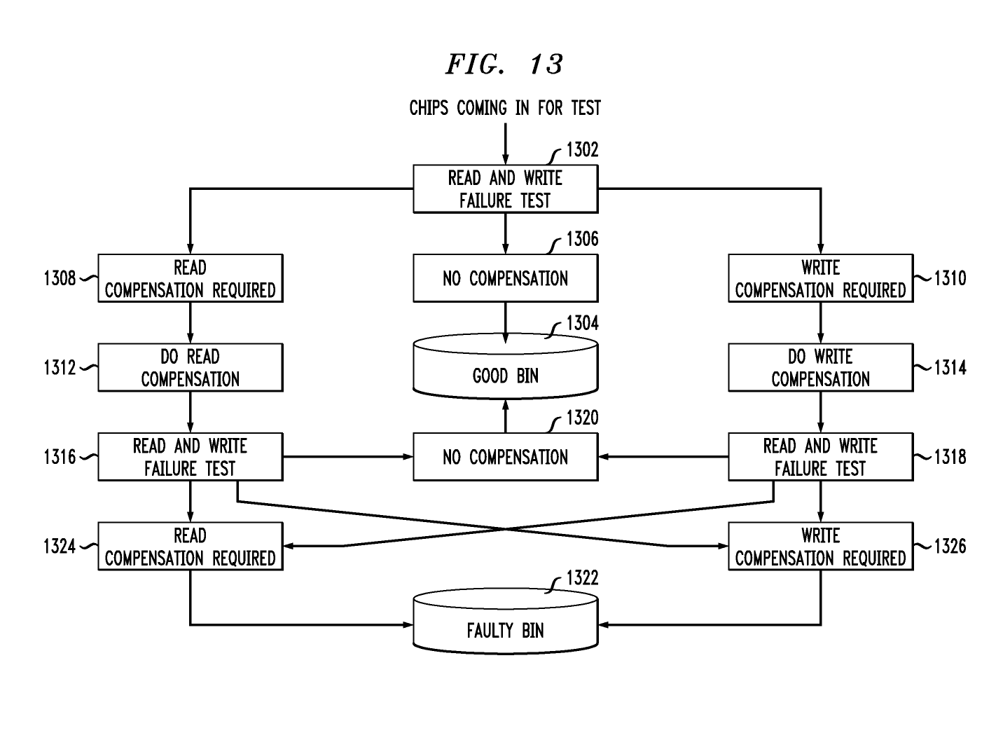

FIG. 13 illustrates an exemplary method for adaptive repair, according to a further aspect of the invention. First, the adaptive repair circuit tests whether an SRAM die requires a read or write correction, as at block 1302. If it does not require any correction, it is placed in the “GOOD chip” bin 1304, as per block 1306. If it requires one type of correction, for example, read correction as at block 1308 or write correction as at block 1310, the terminal voltages (or body biases) are modified to apply that correction, as at blocks 1312, 1314. In the unlikely case the circuit indicates both types of correction are required, the decision logic can be configured as desired to give priority to any of the events. Next, the sensor outputs are re-measured with the modified cell terminal (or body bias) voltages, as shown at blocks 1316, 1318, to make sure the corrected chip passes both the read and write cases. If it does so, it is placed in the “GOOD chip” bin 1304, as per block 1320; otherwise it is placed in the “BAD chip” bin 1322, as per blocks 1324, 1326.

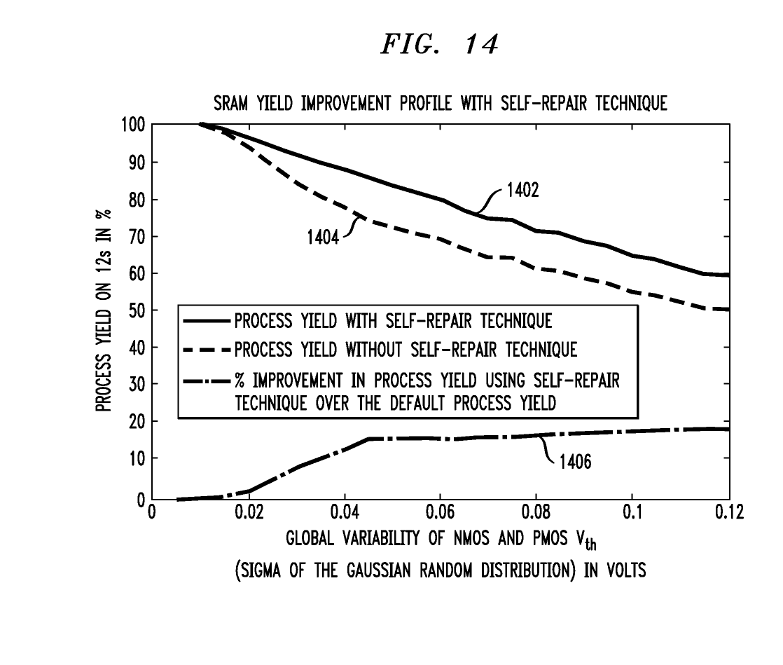

The effectiveness of the proposed invention was verified, for a non-limiting exemplary case, using statistical simulation of a 45 nm PD/SOI SRAM cell. The embodiment with adaptation using the terminal voltages was simulated. FIG. 14 illustrates that the particular inventive SRAM array with the adaptive repair scheme, 1402, has a better parametric yield, as compared to a prior-art SRAM array with no adaptive repair mechanism, 1404, with the percent improvement shown at 1406. It is to be emphasized that more or less advantage may be obtained with different embodiments of the invention, and FIG. 14 is for illustration and not limitation.

Memory cells according to one more aspects of the present invention may be formed into memory circuits, which may be realized as integrated circuits; thus, at least a portion of the techniques of one or more aspects or embodiments of the present invention described herein may be implemented in an integrated circuit. In forming integrated circuits, a plurality of identical die are typically fabricated in a repeated pattern on a surface of a semiconductor wafer. Each die can include one or more of the circuits described herein, and may include other structures or circuits, or circuits having other types of cells. The individual die are cut or diced from the wafer, then packaged as an integrated circuit. A person of skill in the art will know how to dice wafers and package die to produce integrated circuits. Integrated circuits so manufactured are considered part of the present invention. Circuits as described above can be part of the design for an integrated circuit chip. The chip design can be created, for example, in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design can then be converted into an appropriate format such as, for example, Graphic Design System II (GDSII), for the fabrication of photolithographic masks, which typically include multiple copies of the chip design in question that are to be formed on a wafer. The photolithographic masks can be utilized to define areas of the wafer (and/or the layers thereon) to be etched or otherwise processed.

Resulting integrated circuit chips can be distributed by the fabricator in raw wafer form (that is, as a single wafer that has multiple unpackaged chips), as a bare die or in a packaged form. In the latter case, the chip can be mounted in a single chip package (such as a plastic carrier, with leads that are affixed to a mother board or other higher level carrier) or in a multi-chip package (such as a ceramic carrier that has either or both surface interconnections or buried interconnections). In any case, the chip may then be integrated with other chips, discrete circuit elements and/or other signal processing devices as part of either (a) an intermediate product, such as a mother board, or (b) an end product. The end product can be any product that includes integrated circuit chips, ranging from toys and other low-end applications to advanced computer products having a display, a keyboard or other input device, and a central processor.

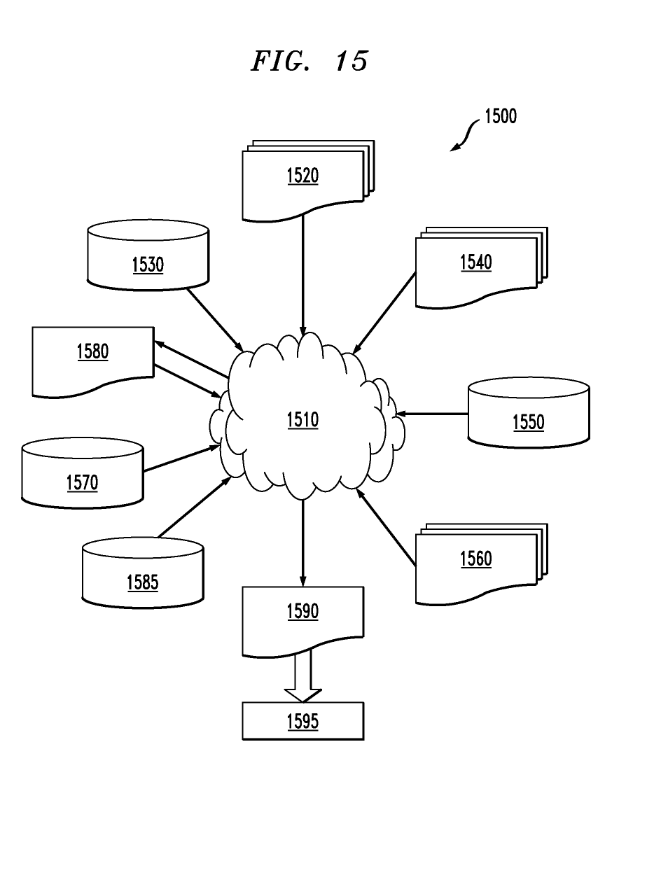

FIG. 15 shows a block diagram of an exemplary design flow 1500 used for example, in semiconductor design, manufacturing, and/or test. Design flow 1500 may vary depending on the type of IC being designed. For example, a design flow 1500 for building an application specific IC (ASIC) may differ from a design flow 1500 for designing a standard component. Design structure 1520 is preferably an input to a design process 1510 and may come from an IP provider, a core developer, or other design company or may be generated by the operator of the design flow, or from other sources. Design structure 1520 comprises, for example, an embodiment of the invention as shown in FIGS. 3, 7, 8, 9, and/or 11 in the form of schematics or HDL, a hardware-description language (e.g., Verilog, VHDL, C, etc.). Design structure 1520 may be contained on one or more machine readable media. For example, design structure 1520 may be a text file or a graphical representation of an embodiment of the invention as shown in FIGS. 3, 7, 8, 9, and/or 11. Design process 1510 preferably synthesizes (or translates) an embodiment of the invention as shown in FIGS. 3, 7, 8, 9, and/or 11 into a netlist 1580, where netlist 1580 is, for example, a list of wires, transistors, logic gates, control circuits, I/O, models, etc. that describes the connections to other elements and circuits in an integrated circuit design and recorded on at least one machine readable medium. This may be an iterative process in which netlist 1580 is re-synthesized one or more times depending on design specifications and parameters for the circuit.

Design process 1510 may include using a variety of inputs; for example, inputs from library elements 1530 which may house a set of commonly used elements, circuits, and devices, including models, layouts, and symbolic representations, for a given manufacturing technology (e.g., different technology nodes, 32 nm, 45 nm, 90 nm, etc.), design specifications 1540, characterization data 1550, verification data 1560, design rules 1570, and test data files 1585 (which may include test patterns and other testing information). Design process 1510 may further include, for example, standard circuit design processes such as timing analysis, verification, design rule checking, place and route operations, etc. One of ordinary skill in the art of integrated circuit design can appreciate the extent of possible electronic design automation tools and applications used in design process 1510 without deviating from the scope and spirit of the invention. The design structure of the invention is not limited to any specific design flow.

Design process 1510 preferably translates an embodiment of the invention as shown in FIGS. 3, 7, 8, 9, and/or 11, along with any additional integrated circuit design or data (if applicable), into a second design structure 1590. Design structure 1590 resides on a storage medium in a data format used for the exchange of layout data of integrated circuits and/or symbolic data format (e.g. information stored in a GDSII (GDS2), GL1, OASIS, map files, or any other suitable format for storing such design structures). Design structure 1590 may comprise information such as, for example, symbolic data, map files, test data files, design content files, manufacturing data, layout parameters, wires, levels of metal, vias, shapes, data for routing through the manufacturing line, and any other data required by a semiconductor manufacturer to produce an embodiment of the invention as shown in FIGS. 3, 7, 8, 9, and/or 11. Design stricture 1590 may then proceed to a stage 1595 where, for example, design structure 1590: proceeds to tape-out, is released to manufacturing, is released to a mask house, is sent to another design house, is sent back to the customer, etc.

It will be appreciated and should be understood that the exemplary embodiments of the invention described above can be implemented in a number of different fashions. Given the teachings of the invention provided herein, one of ordinary skill in the related art will be able to contemplate other implementations of the invention.

Although illustrative embodiments of the present invention have been described herein with reference to the accompanying drawings, it is to be understood that the invention is not limited to those precise embodiments, and that various other changes and modifications may be made by one skilled in the art without departing from the scope of spirit of the invention.

What is claimed is:

1. A static random access memory circuit comprising:
a static random access memory array having a plurality of cells, in turn having a plurality of devices;
a global sensor having at least one output, coupled to said static random access memory array, and configured to sense at least one of global readability and global write-ability;
a decision-making circuit coupled to said at least one output of said global sensor, said decision-making circuit being configured to determine, from said at least one output of said global sensor, whether adaptation signals are required to correct said at least one of global readability and write-ability; and
an adaptation signal generation block, coupled to said decision-making circuit and said array, and configured to supply said adaptation signals to said array, responsive to said decision-making circuit determining that said adaptation signals are required;
wherein at least said array and said global sensor are realized in a single integrated circuit.

2. The static random access memory circuit of claim 1, wherein said global sensor has at least two outputs and is configured to sense both said global readability and said global write-ability.

3. The static random access memory circuit of claim 1, wherein said array, said global sensor, said decision-making circuit, and said adaptation signal-generating block are all realized in said single integrated circuit.

4. The static random access memory circuit of claim 3, wherein said adaptation signal generation block is configured to supply said adaptation signals to said array as at least one of a cell terminal voltage and a word line voltage.

5. The static random access memory circuit of claim 4, wherein said adaptation signal generation block is configured to supply said cell terminal voltage as an off-nominal value, fixed for both read and write operations, in a case when correction of said write-ability is required.

6. The static random access memory circuit of claim 4, wherein said adaptation signal generation block is configured to supply said word line voltage as an off-nominal value, fixed for both read and write operations, in a case when correction of said readability is required.

7. The static random access memory circuit of claim 3, wherein:
some of said devices comprise n-type devices and some of said devices comprise p-type devices, bodies of said n-type devices being interconnected and bodies of said p-type devices being interconnected; and
said adaptation signal generation block is configured to supply said adaptation signals to said array as a first body bias voltage for said p-type devices and a second body bias voltage for said n-type devices.

8. The static random access memory circuit of claim 3, wherein said global sensor comprises a readability sensor and a write-ability sensor, and wherein said readability sensor in turn comprises:
a sensing cell having a trip voltage terminal and a read voltage terminal;
a differential PMOS transistor pair having a first transistor with a drain connected to said trip voltage terminal and a gate connected to said read voltage terminal, and having a second transistor with a grounded gate and a drain maintained at a read reference voltage, each of said transistors of said pair having a source; and
a current comparator coupled to said sources of said transistors of said PMOS pair and configured to compare a current through said first transistor of said pair with a current through said second transistor of said pair, said current comparator having an output;
wherein said output of said current comparator indicates that read correction is required when said current through said second transistor of said pair becomes higher than said current through said first transistor of said pair.

9. The static random access memory circuit of claim 8, wherein said sensing cell comprises a plurality of individual modified six-transistor static random access memory cells connected in parallel.

10. The static random access memory circuit of claim 8, wherein said sensing cell comprises a single modified six-transistor static random access memory cell with large lumped devices.

11. The static random access memory circuit of claim 3, wherein said global sensor comprises a readability sensor and a write-ability sensor, and wherein said write-ability sensor in turn comprises:
a write-ability sensor array having left and right storage nodes and having a word line voltage terminal;
a current sense amplifier coupled to said write-ability sensor array; and
a sense amplifier latch coupled to said current sense amplifier;
wherein said current sense amplifier and said sense amplifier latch are configured to sample and compare voltages at said storage nodes at a negative transition edge of a word line signal applied to said word line voltage terminal, to determine whether a correct write operation has been performed.

12. The static random access memory circuit of claim 11, wherein said write-ability sensor array comprises a plurality of individual un-modified six-transistor static random access memory cells connected in parallel.

13. The static random access memory circuit of claim 8, wherein said write-ability sensor array comprises a single un-modified six-transistor static random access memory cells with large lumped devices.

14. A method for compensating static random access memory chips, said method comprising the steps of:
obtaining a plurality of said chips, each of said chips comprising:
a static random access memory array having a plurality of cells, in turn having a plurality of devices;
a global sensor having at least one output, coupled to said static random access memory array, and configured to sense at least one of global readability and global write-ability;
a decision-making circuit coupled to said at least one output of said global sensor, said decision-making circuit being configured to determine, from said at least one output of said global sensor, whether adaptation signals are required to correct said at least one of global readability and write-ability; and
an adaptation signal generation block, coupled to said decision-making circuit and said array, and configured to supply said adaptation signals to said array, responsive to said decision-making circuit determining that said adaptation signals are required;
testing each of said chips to determined whether at least one of read and write compensation is required;
for those of said chips for which neither read nor write compensation is required, designating said chips as “good”;
performing write compensation for those of said chips where write compensation is required;
performing read compensation for those of said chips where read compensation is required; and
re-testing those of said chips where at least one of read and write compensation was performed, wherein those of said chips which pass said re-test are designated as “good” and those of said chips which fail said re-test are designated as “faulty.”

15. A design structure embodied in a machine readable medium, said design stricture comprising a static random access memory circuit, said static random access memory circuit in turn comprising:
a static random access memory array having a plurality of cells, in turn having a plurality of devices;
a global sensor having at least one output, coupled to said static random access memory array, and configured to sense at least one of global readability and global write-ability;
a decision-making circuit coupled to said at least one output of said global sensor, said decision-making circuit being configured to determine, from said at least one output of said global sensor, whether adaptation signals are required to correct said at least one of global readability and write-ability; and
an adaptation signal generation block, coupled to said decision-making circuit and said array, and configured to supply said adaptation signals to said array, responsive to said decision-making circuit determining that said adaptation signals are required;
wherein at least said array and said global sensor are realized in a single integrated circuit.

16. The design structure of claim 15, wherein said global sensor has at least two outputs and is configured to sense both said global readability and said global write-ability.

17. The design structure of claim 16, wherein said array, said global sensor, said decision-making circuit, and said adaptation signal-generating block are all realized in said single integrated circuit.

18. The design structure of claim 17, wherein said adaptation signal generation block is configured to supply said adaptation signals to said array as at least one of a cell terminal voltage and a word line voltage.

19. The design structure of claim 18, wherein said adaptation signal generation block is configured to supply said cell terminal voltage as an off-nominal value, fixed for both read and write operations, in a case when correction of said write-ability is required, and wherein said adaptation signal generation block is configured to supply said word line voltage as an off-nominal value, fixed for both said read and said write operations, in a case when correction of said readability is required.

20. The design structure of claim 17, wherein:
some of said devices comprise n-type devices and some of said devices comprise p-type devices, bodies of said n-type devices being interconnected and bodies of said p-type devices being interconnected; and
said adaptation signal generation block is configured to supply said adaptation signals to said array as a first body bias voltage for said p-type devices and a second body bias voltage for said n-type devices.
